(19) United States
(12) Patent Application Publication
(10) Pub. No.: US 2001/0004119 A1
(43) Pub. Date: Jun. 21, 2001

(54) Non-volatile memory device and manufacturing process thereof

(76) Inventors: Alessandra Foraboschi, Milano (IT); Luca Zanotti, Agrate Brianza (IT)

Correspondence Address: James H. Morris, Wolf, Greenfield & Sacks, P.C,, Federal Reserve Plaza, 600 Atlantic Avenue, Boston, MA, 02210-2211, US

(21) Appl. No.: 09/731,065

(22) Filed: Dec. 6, 2000

(30) Foreign Application Priority Data
Dec. 20, 1999 (IT) MI99A002650

(51) Int. Cl. H01L 29/788

(52) U.S. Cl. 257/315

(57) ABSTRACT

A non-volatile memory device including memory cells each formed as a MOS transistor having source and drain regions and gate structures is described. The source and drain regions and the gate structures are covered by a silicon nitride layer obtained in a standard PECVD chamber at a temperature lower than 480 ° C. and with a suitable gas flow. An insulated layer is placed over the silicon nitride layer.

### BACKGROUND OF THE INVENTION

1. Field of the Invention

The present invention relates to a non-volatile memory device and also to a process for manufacturing the device.

2. Discussion of the Related Art

Semiconductor devices are generally known wherein insulated material layers are present between the active regions and the first metal layer, which are utilized for insulating the active regions of the device from each other in order to open the contact windows which will be filled up with the metal. Such insulated material layers, in the case of the non-volatile memory devices, also provide for other purposes, the main one being to contribute to the retention of the charge stored in the memory cells of the device. In fact, the charge could be dispersed, and, therefore, it could result in a failed non-volatile memory device due to possible resistive pathways for the current which are between the metal layer and the active regions of the memory cells where the charge is stored.

Such insulated material layers are generally formed by a small thickness silicon oxide layer and a borophosphosilicate layer (BPSG) which has a higher thickness than the oxide layer.

In view of the state of the art described, it is an object of the present invention to form a non-volatile memory device which is new with respect to the known non-volatile memory devices and allows high performance.

It is another object of the present invention to process a process for manufacturing the aforementioned device.

### SUMMARY OF THE INVENTION

According to the present invention, these and other objects are provided by a non-volatile memory device comprising memory cells each formed as a MOS transistor having source and drain regions and gate structures, wherein the source and drain regions and the gate structures are covered by a silicon nitride layer obtained in a standard PECVD chamber at a temperature lower than 480° C. and with a suitable gas flow and an insulated layer is placed over said silicon nitride layer.

As a result of the present invention it is possible to form a non-volatile memory device which, as a result of a pre-metal insulated layer comprising a silicon nitride layer, allows the performance of the device to improve and above all it increases the ability of the device to maintain the charge stored therein.

The invention also provides a process for manufacturing a non-volatile memory device comprising memory cells each formed as a MOS transistor, the process comprising a first step for formation, over a substrate of a first conductivity type, of source and drain regions of the memory cells of a second conductivity type, a second step for formation of gate structures of the memory cells, a third step for formation of metal and insulated layers and a further step for deposition of a passivation material, wherein, between the second step and the third step a step for deposition of a silicon nitride layer over the source and drain regions and the gate structures in a standard PECVD chamber at a temperature than lower 480° C. and with a suitable gas flow, and a successive step for formation of an insulated layer.

### BRIEF DESCRIPTION OF THE DRAWINGS

The features and the advantages of the present invention will be made evident by the following detailed description of a particular embodiment thereof, illustrated as not limiting example in the annexed drawings, wherein:

FIG. 1 is a schematic cross-sectional view of a cell of a non-volatile memory device according to present invention;

FIG. 2 is a schematic view of a standard PECVD chamber.

### DETAILED DESCRIPTION

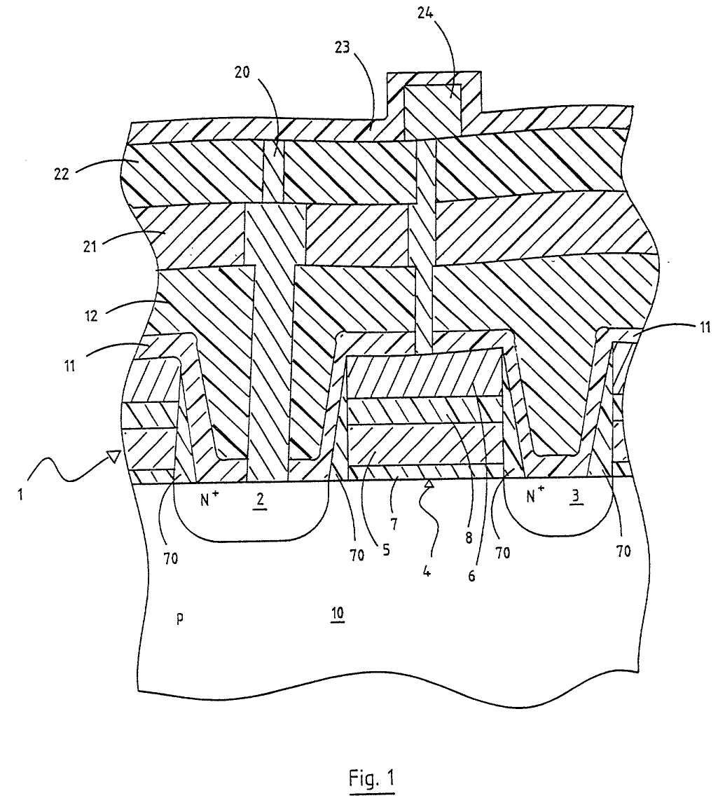

Referring to FIG. 1, a section of a cell 1 of a non-volatile memory device according to invention is shown.

The memory cell 1 is formed, as known, by N⁺-type source 2 and drain 3 regions on a P-type substrate 10, by a gate structure 4 and by dielectric spacers 70. The gate structure 4 is formed by polysilicon layers 5 and 6 alternated with silicon oxide layers 7 and 8.

A silicon nitride layer 11 located under a borophosphosilicate layer 12 (BPSG) is placed on the active regions of the memory cell, according to invention. The silicon nitride layer 11 has a thickness ranging from 50 angstroms to 1000 angstroms. More specifically, the thickness of the silicon nitride layer 11 can range from 50 angstroms to 400 angstroms if a borderless contact process (that is a process to form contact windows so that active regions are contacted in completely absent edge regions) is not required, while if such borderless contact process is formed the thickness of the silicon nitride layer 11 ranges from 200 angstroms to 1000 angstroms. The silicon nitride layer 11 is deposited by PECVD (plasma enhanced chemical vapor deposition) or HDPCVD (high density plasma chemical vapor deposition) at a temperature lower than 480° C., which preferably ranges from 360° C. to 360° C., with a hydrogen concentration lower than 18% and with a deposition rate of 150 nm/min.

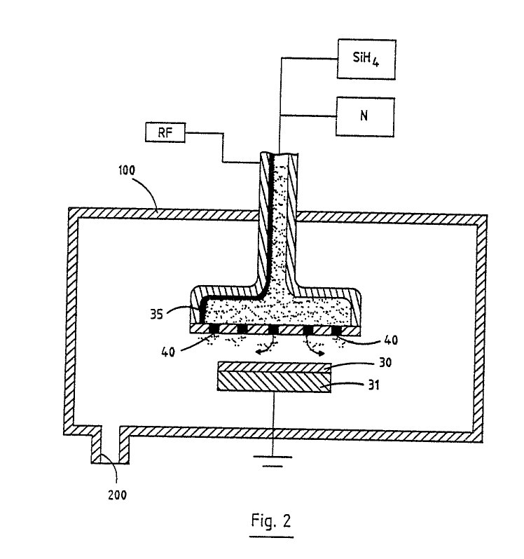

In a standard PECVD chamber 100, that is without hardware modifications, of the type described in FIG. 2, the semiconductor wafer 30, where the memory cells 1 will be produced, is disposed on a first electrode 31 connected to ground while a second electrode 35 connected to a radio-frequency source RF faces on the top surface of the wafer 30. Said second electrode 35 is provided with holes 40 on its bottom surface for injecting suitable gases into the wafer 30 in the chamber 1. The formation of the silicon nitride layer is made by a suitable gas flow, that is SiH4 ranging from 20 sccm (Standard Cubic Centimeter per Minute) to 100 sccm and nitrogen ranging from 1500 sccm to 3000 sccm, with a plasma power ranging from 300 W to 800 W and with a spacing between the electrodes which ranges from 200 mils to 500 mils. It is also possible to utilize He as dilution gas to better conform the plasma. The escape of the exhaust gases is through the conduct 200.

The borophosphosilicate layer 12 can be formed by different BPSG layers having different boron and phosphorus concentrations.

Insulated layers 21 and 22, for example silicon oxide, and metal layers 20 and 24 filling up the contact windows to contact the source region 2, the drain region 3 and the gate 6, and a passivation layer 23 are placed on the BPSG layer 12 in a known way.

As a variant of the present invention an undoped silicon oxide layer 12 can be utilized instead of the borophosphosilicate layer 12.

The nitride layer 11 and the borophosphosilicate or undoped silicon oxide layer 12 allows higher performance of the non-volatile memory cells and mainly a higher charge retention.

The memory device described before is produced by a process showing different steps with respect to the known processes.

After the known steps for the formation of the active regions of the memory cells, that is the source region 2, the drain region 3, the gate structure 4 and the dielectric spacers 70, a step for forming a pre-metal layer according to invention occurs. Such step provides a first sub-step wherein a deposition of a silicon nitride layer 11 having a certain thickness occurs. Such deposition occurs in a standard PECVD chamber 100, that is of the type shown in FIG. 2 and as previously described, or in a standard HDPCVD chamber at a temperature lower than 480° C., which preferably ranges from 360° C. to 380° C., and at a deposition rate lower than 150 nm/min. In the PECVD chamber 100 the deposition of the silicon nitride layer 11 is made with a suitable gas flow, that is SiH4 ranging from 20 sccm to 100 sccm and nitrogen ranging from 1500 sccm to 3000 sccm, with a plasma power ranging from 300 W to 800 W and with a spacing between the electrodes which ranges from 200 mils to 500 mils. It is possible to utilize He as a dilution gas to better conform the plasma.

The step for the formation of a pre-metal layer provides for a second sub-step for the formation of a borophosphosilicate layer 12 or different BPSG layers having different boron and phosphorus concentrations.

After the step for the formation of a pre-metal layer the known steps for the formation of the insulated layers 21 and 22 (for example silicon oxide) and for the formation of the contact windows filled up with metal layers 20 and 24, metal and a passivation layer 23 occur.

As a variant of the present invention an undoped silicon oxide layer 12 can be utilized instead of the borophosphosilicate layer 12.

A layer formed by the silicon nitride 11 and borophosphosilicate 12 layers as above described can be also utilized for the formation of a pre-metal layer in any semiconductor device in a borderless contact process.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A non-volatile memory device comprising memory cells each formed as a MOS transistor having source and drain regions and gate structures, wherein the source and drain regions and the gate structures are covered by a silicon nitride layer obtained in a standard PECVD chamber at a temperature lower than 480° C. and with a suitable gas flow and an insulated layer is placed over the silicon nitride layer.

2. A memory device according to claim 1, wherein the insulated layer is a borophosphosilicate layer.

3. A memory device according to claim 1, wherein the insulated layer is an undoped silicon oxide layer.

4. A memory device according to claim 1, wherein the silicon nitride layer has a thickness ranging from 50 angstroms to 1000 angstroms.

5. A memory device according to claim 1, wherein the silicon nitride layer is obtained at a deposition rate lower than 150 nm/min and with a plasma power ranging from 300 W to 800 W.

6. A memory device according to claim 1, wherein the suitable gas flow comprises a SiH4 flow ranging from 20 sccm to 100 sccm and a nitrogen flow ranging from 1500 sccm to 3000 sccm.

7. A memory device according to claim 1, wherein the silicon nitride layer has a hydrogen concentration lower than 18%.

8. A process for manufacturing a non-volatile memory device comprising memory cells each formed as a MOS transistor, the process comprising a first step for formation, over a substrate of a first conductivity type, of source and drain regions of the memory cells of a second conductivity type, a second step for formation of gate structures of the memory cells, a third step for formation of metal and insulated layers and a further step for deposition of a passivation material, wherein, between the second step and the third step a step for deposition of a silicon nitride layer over the source and drain regions and the gate structures in a standard PECVD chamber at a temperature than lower 480° C. and with a suitable gas flow, and a successive step for formation of an insulated layer.

9. A process according to claim 8, wherein the insulated layer is a borophosphosilicate layer.

10. A process according to claim 8, wherein the insulated layer is an undoped silicon oxide layer.

11. A process according to claim 8, wherein the silicon nitride layer has a thickness ranging from 50 angstroms to 1000 angstroms.

12. A process according to claim 8, wherein the silicon nitride layer is obtained at a deposition rate lower than 150 nm/min and with a plasma power ranging from 300 W to 800 W.

13. A process according to claim 8, wherein the suitable gas flow comprises a SiH4 flow ranging from 20 sccm to 100 sccm and a nitrogen flow ranging from 1500 sccm to 3000 sccm.

14. A process according to claim 8, wherein the silicon nitride layer has a hydrogen concentration lower than 18%.
